(19) United States
(12) Patent Application Publication
(10) Pub. No.: US 2014/0136128 A1
(43) Pub. Date: May 15, 2014

(54) APPARATUS AND METHOD FOR SENSING TRANSISTOR AGING EFFECTS

(71) Applicant: LSI CORPORATION, Milpitas, CA (US)

(72) Inventors: James D. Chlipala, Emmaus, PA (US); Michael S. Buonpane, Easton, PA (US); Scott A. Segan, Allentown, PA (US); Richard P. Martin, Macungie, PA (US); Richard Muscavage, Gilbertsville, PA (US)

(73) Assignee: LSI Corporation, Milpitas, CA (US)

(21) Appl. No.: 13/673,730

(22) Filed: Nov. 9, 2012

(51) Int. Cl. G01R 31/26; G06F 19/00

(52) U.S. Cl. CPC G01R 31/2642; G06F 19/00
USPC 702/58

(57) ABSTRACT

An integrated circuit implements a transistor aging effects sensor comprising first and second delay lines, each comprising a plurality of delay elements, and a register. The register comprises a plurality of flip-flops having data inputs driven by respective outputs of respective ones of the delay elements of the first delay line and clock inputs driven by one or more clock signals provided by at least one of the delay elements of the second delay line. Data outputs of the flip-flops of the register are indicative of one or more aging effects in transistors of the first and second delay lines. For example, the register may comprise a thermometer encoded register providing digital output signals used to determine aging effects in the transistors of the first and second delay lines. Embodiments can be implemented using differential delay lines or delay lines comprising respective inverter chains.

### BACKGROUND

Integrated circuits are often designed to incorporate various types of test circuitry. For example, it is well known to configure an integrated circuit to include scan test circuitry that facilitates testing for various internal fault conditions using applied test patterns. These internal fault conditions in many cases can be attributable at least in part to process-dependent differences in speed, drive strength or other characteristics between transistors of different conductivity types, such as n-type metal-oxide-semiconductor (NMOS) transistors and p-type metal-oxide-semiconductor (PMOS) transistors.

It is also well known that transistor characteristics can change with constant transistor use over a relatively long period of time, particularly if certain bias conditions are continuously maintained throughout that period. This variation in transistor characteristics over long periods of time is generally referred to as transistor aging. Typical manifestations of transistor aging include effects such as increases in the absolute value of transistor threshold voltages and decreases in charge carrier mobilities. Such aging effects can compromise the performance of the integrated circuit that incorporates the corresponding transistors.

Transistor aging effects may be categorized as including, for example, negative bias temperature aging effects and positive bias temperature aging effects. These aging effects are also collectively referred to as bias temperature instability type aging effects. Bias temperature instability type aging impacts transistors which are biased “on” for a long period of time, typically for a period of time on the order of years. More particularly, transistors that are susceptible to negative bias temperature aging include PMOS transistors continuously biased such that gate voltage is more than one threshold voltage lower than source voltage, and transistors that are susceptible to positive bias temperature aging include NMOS transistors continuously biased such that gate voltage is more than one threshold voltage higher than source voltage. These types of aging effects tend to “weaken” the transistors, and in extreme cases can cause circuit malfunction.

It is therefore often desirable to implement functionality for sensing transistor aging effects in an integrated circuit. For example, in conjunction with scan testing or other types of testing, transistor aging effects measurements may be useful in determining particular test patterns to apply, or in interpreting or otherwise processing test results. Additionally or alternatively, such measurements may be used in characterizing the ability of an integrated circuit to meet performance requirements under various environmental conditions, or in adjusting manufacturing processes to increase integrated circuit yield.

Unfortunately, conventional techniques generally fail to provide a sufficient level of accuracy and efficiency in the sensing of transistor aging effects. For example, typical conventional techniques involve comparing the output frequencies of first and second on-chip oscillators configured in substantially the same manner, but with one of the oscillators including transistors that are subject to aging conditions and the other oscillator not including transistors that are subject to the aging conditions. However, these techniques are problematic in that the measurement time is usually on the order of multiple oscillator periods. More particularly, such techniques cannot adequately account for the impact of a phenomenon known as recovery, where transistor aging effects are partially reversed within a timeframe of microseconds after the continuous bias or other aging conditions have been removed, since the measurement time is often close to or greater than the recovery time.

Such techniques also typically require the use of analog circuitry that can be difficult to incorporate into an integrated circuit, and can consume excessive amounts of power within the integrated circuit. Also, the measurements generated by conventional techniques are typically not independent of voltage, temperature or clock frequency.

It is therefore difficult using these and other conventional techniques to obtain an accurate and efficient measurement of transistor aging that is not adversely influenced by recovery.

### SUMMARY

Embodiments of the invention provide improved transistor aging effects sensors that may be implemented within an integrated circuit and controlled, for example, by an external or internal tester. Such sensors can be configured to separately measure accumulated aging effects in NMOS and PMOS transistors in an accurate and efficient manner that is not adversely influenced by recovery.

In one embodiment, an integrated circuit implements a transistor aging effects sensor. The transistor aging effects sensor comprises first and second delay lines, each comprising a plurality of delay elements, and a register. The register comprises a plurality of flip-flops having data inputs driven by respective outputs of respective ones of the delay elements of the first delay line and clock inputs driven by one or more clock signals provided by at least one of the delay elements of the second delay line. Data outputs of the flip-flops of the register are indicative of one or more aging effects in transistors of the first and second delay lines.

By way of example, the register may illustratively comprise a thermometer encoded register providing at least one digital output signal used to determine aging effects in the transistors of the first and second delay lines. The thermometer encoded register in such an arrangement may more particularly comprise a first bank of flip-flops providing a first digital output signal that is utilized to determine one or more aging effects in NMOS transistors of the first and second delay lines, and a second bank of flip-flops providing a second digital output signal that is utilized to determine one or more aging effects in PMOS transistors of the first and second delay lines.

The first and second delay lines may comprise respective differential delay lines in which the delay elements comprise respective differential delay elements. In an arrangement of this type, the flip-flops of the first bank of flip-flops have data inputs driven by respective first outputs of respective differential delay elements of the first delay line and clock inputs driven by a first set of clock signals provided by at least one of the delay elements of the second delay line. Similarly, the flip-flops of the second bank of flip-flops have data inputs driven by respective second outputs of respective differential delay elements of the first delay line and clock inputs driven by a second set of clock signals provided by at least one of the delay elements of the second delay line.

In other embodiments, the first and second delay lines may comprise respective inverter chains in which the delay elements comprise respective inverters.

One or more of the illustrative embodiments provide significant improvements relative to conventional practice. For example, measurements can be made very quickly, in an amount of time that is orders of magnitude less than the typical recovery time of the impacted transistors, such that the measurements are highly accurate and not adversely influenced by recovery. In addition, a given such embodiment is implemented in the form of an all-digital transistor aging effects sensor in which measurements are substantially independent of voltage and temperature. Also, the aging effects sensor is implemented in a self-timed configuration, such that the measurements are substantially independent of clock frequency. Moreover, the aging effects sensor is implemented so as to consume dynamic power only when making a measurement, and therefore without unduly increasing the power consumption of the corresponding integrated circuit.

### BRIEF DESCRIPTION OF THE DRAWINGS

FIG. 1 is a block diagram of an integrated circuit testing system comprising an integrated circuit that incorporates a transistor aging effects sensor in an illustrative embodiment.

FIG. 2 shows a more detailed view of one embodiment of a tester of the FIG. 1 system.

FIGS. 3A and 3B show a more detailed view of one embodiment of the transistor aging effects sensor of the FIG. 1 system, with FIG. 3B specifically illustrating an exemplary delay element of a given one of the delay lines of FIG. 3A. These figures are collectively referred to herein as FIG. 3.

FIGS. 4 through 15 are timing diagrams illustrating the operation of the FIG. 3 transistor aging effects sensor.

### DETAILED DESCRIPTION

Embodiments of the invention will be illustrated herein in conjunction with exemplary testing systems and associated integrated circuits comprising transistor aging effects sensors configured to determine amounts of aging occurring in NMOS and PMOS transistors of the integrated circuits. It should be understood, however, that embodiments of the invention are more generally applicable to any testing system or associated integrated circuit in which it is desirable to provide sensing of transistor aging effects. Additional embodiments may be implemented using components other than those specifically shown and described in conjunction with the illustrative embodiments.

FIG. 1 shows an embodiment of the invention in which a testing system 100 comprises an integrated circuit 102 coupled to a tester 104. The integrated circuit 102 comprises a transistor aging effects sensor 110 and additional circuitry 112. The tester 104 in the present embodiment is an external tester relative to the integrated circuit 102. In other embodiments, at least a portion of the tester 104 may be incorporated into the integrated circuit 102. For example, substantially the entire tester 104 may be incorporated into the integrated circuit 102, as in a built-in self-test (BIST) arrangement.

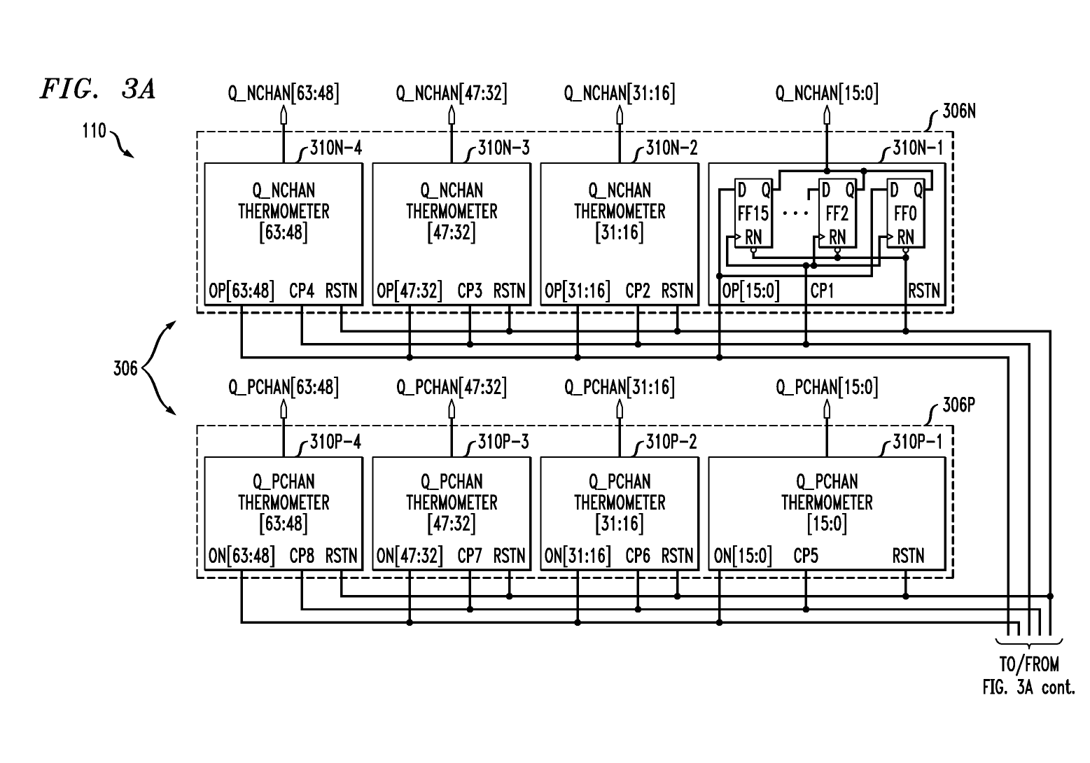

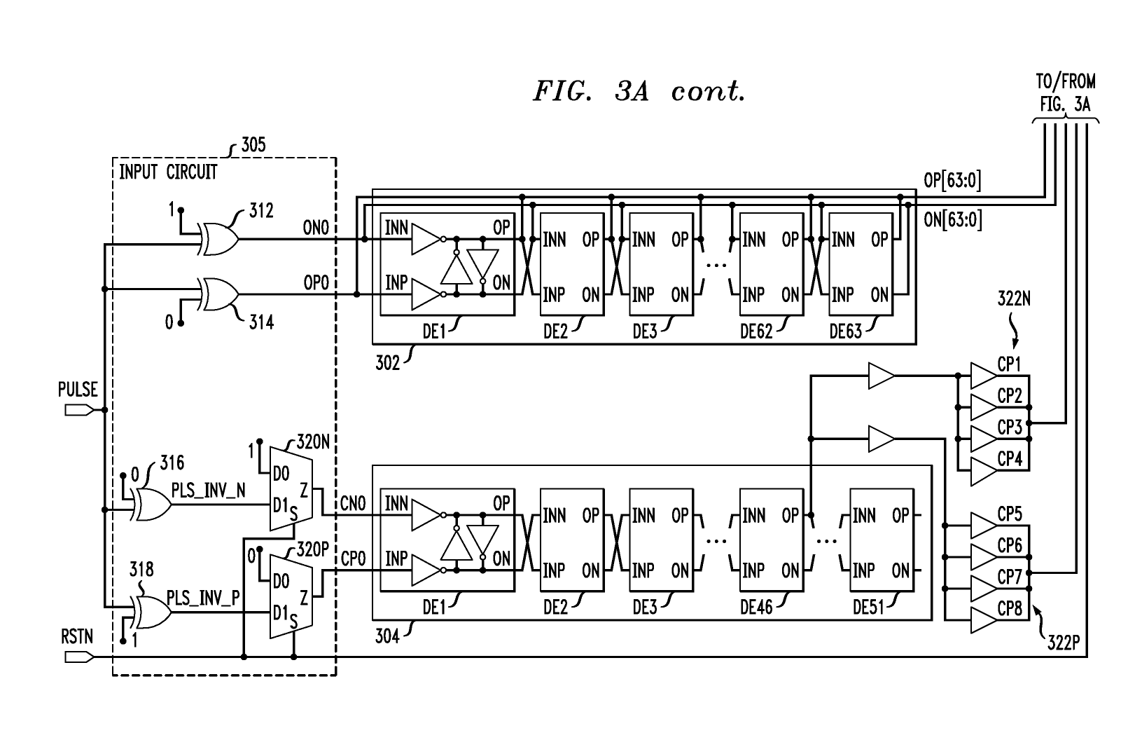

As will be described in greater detail below in conjunction with FIGS. 3 through 15, the transistor aging effects sensor 110 of integrated circuit 102 in one embodiment comprises first and second delay lines, each comprising a plurality of delay elements, and a register. The register comprises a plurality of flip-flops having data inputs driven by respective outputs of respective ones of the delay elements of the first delay line and clock inputs driven by one or more clock signals provided by at least one of the delay elements of the second delay line. The data outputs of the flip-flops of the register are indicative of one or more aging effects in transistors of the first and second delay lines. The register may be implemented, for example, as an output register comprising multiple banks of flip-flops, or in a wide variety of other configurations.

The term “aging effects” as used herein is intended to be broadly construed so as to encompass, for example, differences in speed, drive strength or other transistor characteristics that occur over long periods of time when a transistor is subject to substantially continuous bias conditions or other aging conditions.

The additional circuitry 112 may comprise, for example, multiple integrated circuit cores, such as respective read channel and additional cores of a system-on-chip (SOC) integrated circuit in a hard disk drive (HDD) controller application, designed for reading and writing data from one or more magnetic storage disks of an HDD. In other embodiments, the additional circuitry 112 may comprise other types of functional logic circuitry, in any combination, and the term “additional circuitry” is intended to be broadly construed so as to cover any such arrangements of logic circuitry.

The particular configuration of testing system 100 as shown in FIG. 1 is exemplary only, and the testing system 100 in other embodiments may include other elements in addition to or in place of those specifically shown, including one or more elements of a type commonly found in a conventional implementation of such a system. For example, various elements of the integrated circuit 102 or tester 104 may be implemented, by way of illustration only and without limitation, utilizing a microprocessor, central processing unit (CPU), digital signal processor (DSP), application-specific integrated circuit (ASIC), field-programmable gate array (FPGA), or other type of data processing device, as well as portions or combinations of these and other devices.

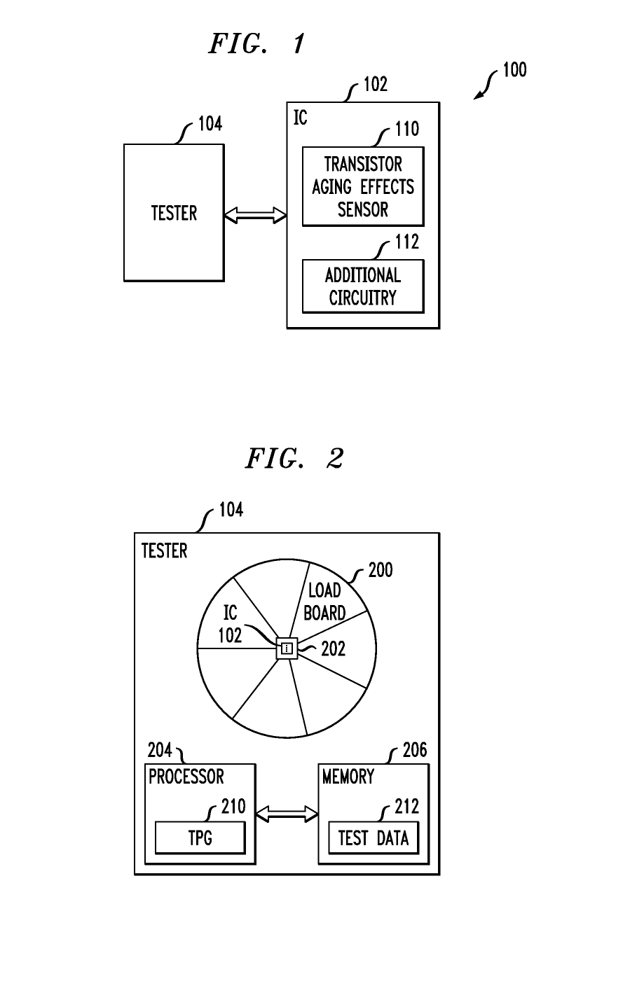

Referring now to FIG. 2, one possible implementation of tester 104 is shown in greater detail. In this embodiment, tester 104 comprises a load board 200. The integrated circuit 102 is to be subject to testing for transistor aging effects using transistor aging effects sensor 110 and is installed in a central portion 202 of the load board 200. The tester 104 also comprises processor and memory elements 204 and 206. In the present embodiment, processor 204 is shown as implementing a test pattern generator 210, also denoted in the figure as a TPG. Associated test data 212 is stored in memory 206. The test data may include, for example, transistor aging effects test results obtained by utilizing the transistor aging effects sensor 110 under the control of one or more test signals generated by the tester 104.

Portions of the tester 104 may be implemented at least in part in the form of software stored in memory 206 and executed by processor 204. For example, the memory 206 may store program code that is executed by the processor 204 to implement particular testing operations that utilize the transistor aging effects sensor 110 of integrated circuit 102. The memory 206 is an example of what is more generally referred to herein as a computer-readable medium or other type of computer program product having computer program code embodied therein, and may comprise, for example, electronic memory such as RAM or ROM, magnetic memory, optical memory, or other types of storage devices in any combination. The processor 204 may comprise a microprocessor, CPU, ASIC, FPGA or other type of processing device, as well as portions or combinations of such devices. Similar processor and memory elements may be used to implement at least a portion of the transistor aging effects sensor 110, as well as other portions of the integrated circuit 102.

It should be noted that the FIG. 2 embodiment of tester 104 should not be construed as limiting in any way. In other embodiments, various conventional testing system arrangements can be modified in a straightforward manner to support the transistor aging effects sensing functionality disclosed herein. Accordingly, numerous alternative testers may be used to perform transistor aging effects testing of an integrated circuit as disclosed herein. Also, as indicated previously, in other embodiments one or more portions of an external tester may be incorporated into the integrated circuit itself, as in BIST arrangement.

With reference now to FIG. 3A, an embodiment of the transistor aging effects sensor 110 comprises first and second delay lines 302 and 304 each comprising a plurality of delay elements. The first and second delay lines are driven by an input circuit 305. The transistor aging effects sensor 110 further includes a register 306 comprising a plurality of flip-flops having data inputs driven by respective outputs of respective ones of the delay elements of the first delay line and clock inputs driven by one or more clock signals provided by at least one of the delay elements of the second delay line. Data outputs of the flip-flops of the register 306 are indicative of one or more aging effects in transistors of the first and second delay lines 302 and 304.

The first and second delay lines 302 and 304 comprise respective differential delay lines in which the delay elements comprise respective differential delay elements. The first delay line 302 more particularly comprises a plurality of differential delay elements DE1, DE2, DE3, . . . DE63, and the second delay line 304 more particularly comprises a plurality of differential delay elements DE1, DE2, DE3, . . . . DE51. In other embodiments, different numbers, types and arrangements of delay elements may be used in the delay lines 302 and 304. For example, as will be described in more detail below, other embodiments can implement the first and second delay lines as respective inverter chains in which the delay elements comprise respective inverters.

Each of the differential delay elements of the first and second delay lines 302 and 304 in the present embodiment illustratively comprises four inverters, including two series inverters that pass respective ones of two delay element inputs INN and INP to two corresponding outputs OP and ON, and a pair of cross-coupled weak inverters connected in parallel between the two outputs so as to balance output rise and fall times. This exemplary differential delay element provides a timing resolution of one inverter delay.

Also, the outputs of each differential delay element are cross-coupled to the inputs of the next differential delay element of the delay line. Thus, for example, outputs OP and ON of the first differential delay element DE1 in delay line 302 are cross-coupled to respective inputs INP and INN of the second differential delay element DE2 in delay line 302. The other differential delay elements of the first and second delay lines are interconnected with one another in a similar manner. Other differential delay element circuitry and interconnection arrangements may be used in other embodiments.

The input circuit 305 generates a first set of complementary input signals ON0 and OP0 for application to the respective differential inputs INN and INP of the first differential delay element DE1 of the first delay line 302, and a second set of complementary input signals CN0 and CP0 for application to respective differential inputs INN and INP of the first differential delay element DE1 of the second delay line 304.

FIG. 3B shows a more detailed view of a given one of the delay elements DE1 of either delay line 302 or delay line 304. As shown, delay element DE1 comprises series inverter I1 arranged between input INN and output OP, series inverter I2 arranged between input INP and output ON, and parallel inverters I3 and I4 cross-coupled between outputs OP and ON. Each of the inverters I1, I2, I3 and I4 of delay element DE1 comprises a PMOS transistor P1 and an NMOS transistor N1. The other delay elements of the delay lines 302 and 304 are assumed to be configured in substantially the same manner.

Referring again to FIG. 3A, the first and second sets of complementary input signals are generated by input circuit 305 in this embodiment from a common pulse input signal, denoted PULSE in the figure. The complementary input signals within a given one of the first and second sets of complementary input signals have substantially aligned transition times, such that, for example, a rising edge of one complementary input signal in the set occurs at substantially the same time as a falling edge of the other complementary input signal in the set.

The first set of complementary input signals ON0 and OP0 is generated in the input circuit 305 using a pair of two-input XOR gates 312 and 314. Each of the XOR gates 312 and 314 receives at one of its inputs the PULSE signal. The XOR gate 312 has its other input coupled to a logic high voltage level, such as Vdd, and the XOR gate 314 has its other input coupled to a logic low voltage level, such as Vss or ground potential.

The second set of complementary input signals CN0 and CP0 is generated in the input circuit 305 using a pair of two-input XOR gates 316 and 318 and associated multiplexing circuitry 320. Each of the XOR gates 316 and 318 receives at one of its inputs the PULSE signal. The XOR gate 316 has its other input coupled to the logic low voltage level, and the XOR gate 318 has its other input coupled to the logic high voltage level.

Complementary signals PLS_INV_N and PLS_INV_P at the outputs of the respective XOR gates 316 and 318 are applied to respective D1 inputs of multiplexers 320N and 320P of the multiplexing circuitry 320. The D0 input of the multiplexer 320N is coupled to the logic high voltage level, and the D0 input of the multiplexer 320P is coupled to the logic low voltage level. The D0 inputs of the multiplexers 320N and 320P represent one example of a set of complementary fixed bias condition input signals. The multiplexing circuitry 320 is therefore configured to select between the set of complementary signals PLS_INV_N and PLS_INV_P and the set of complementary fixed bias condition input signals for application to the differential inputs of the first differential delay element DE1 of the second delay line. The selection is performed using a select signal applied to S inputs of the multiplexers 320N and 320P as indicated.

Accordingly, the multiplexing circuitry 320 can selectively adapt the second set of complementary input signals CN0 and CP0 so as to comprise either the set of complementary signals PLS_INV_N and PLS_INV_P applied to the D1 inputs or the set of fixed bias condition input signals applied to the D0 inputs, under control of a select signal corresponding in this embodiment to an active low reset signal RSTN.

The register 306 in the present embodiment comprises a thermometer encoded register providing at least one digital output signal that is utilized to determine one or more aging effects in transistors of the first and second delay lines 302 and 304. More particularly, the register 306 comprises a first bank of flip-flops 306N providing at least one digital output signal that is utilized to determine one or more aging effects in NMOS transistors of the first and second delay lines 302 and 304, and a second bank of flip-flops 306P providing at least one digital output signal that is utilized to determine one or more aging effects in PMOS transistors of the first and second delay lines 302 and 304.

The thermometer encoded register 306 is an example of what is more generally referred to herein as a “register,” and other types of registers may be used in other embodiments. Such a register comprises a plurality of flip-flops having data inputs driven by respective outputs of respective ones of the delay elements of the first delay line 302 and clock inputs driven by one or more clock signals provided by at least one of the delay elements of the second delay line 304, where data outputs of the flip-flops of the register are indicative of one or more aging effects in transistors of the first and second delay lines.

In the present embodiment, the flip-flops of the first bank of flip-flops 306N have data inputs driven by respective signals OP[63:0], where OP[63:1] denotes the first outputs of respective differential delay elements DE[63:1] of the first delay line and OP[0] denotes the OP0 input to the first delay line, and clock inputs driven by a first set of clock signals CP1, CP2, CP3 and CP4 provided by non-inverting buffers 322N. These clock signals are illustratively derived from the OP output of differential delay element DE46, although in other embodiments may be generated using other outputs of one or more of the differential delay elements DE[51:1] of the second delay line 304.

Similarly, the flip-flops of the second bank of flip-flops 306P have data inputs driven by respective signals ON[63:0], where ON[63:1] denotes the second outputs of respective differential delay elements DE[63:1] of the first delay line and ON[0] denotes the ON0 input to the first delay line, and clock inputs driven by a second set of clock signals CP5, CP6, CP7 and CP8 provided by non-inverting buffers 322P. These clock signals are also illustratively derived from the OP output of differential delay element DE46, although in other embodiments may be generated using other outputs of one or more of the differential delay elements DE[51:1] of the second delay line 304.

Each of the first and second banks of flip-flops 306N and 306P of the thermometer encoded register 306 is further divided into groups as indicated in the figure. More particularly, bank 306N comprises four distinct groups 310N-1, 310N-2, 310N-3 and 310N-4, each comprising 16 flip-flops, and bank 306P comprises four distinct groups 310P-1, 310P-2, 310P-3 and 310P-4, each comprising 16 flip-flops. The flip-flops are shown only for group 310N-1, and include flip-flops FF0 through FF15, although each of the other groups is assumed to comprise a similar arrangement of flip-flops. Also, although D-type flip-flops are used in this embodiment, other embodiments can utilize other types of flip-flops. The term “flip-flop” as used herein is therefore intended to be broadly construed so as to encompass a wide variety of different types of clocked storage elements.

The groups of flip-flops 310N-1, 310N-2, 310N-3 and 310N-4 of bank 306N receive as their data inputs the respective sets of signals OP[15:0], OP[31:16], OP[47:32] and OP[63:48] and are clocked by the respective clock signals CP1, CP2, CP3 and CP4. The groups of flip-flops 310P-1, 310P-2, 310P-3 and 310P-4 of bank 306P receive as their data inputs the respective sets of signals ON[15:0], ON[31:16], ON[47:32] and ON[63:48] and are clocked by the respective clock signals CP5, CP6, CP7 and CP8.

The groups of flip-flops 310N-1, 310N-2, 310N-3 and 310N-4 of bank 306N generate respective output signals Q_NCHAN[15:0], Q_NCHAN[31:16], Q_NCHAN[47:32] and Q_NCHAN[63:48], which may be viewed as comprising different portions of a single digital output signal. The groups of flip-flops 310P-1, 310P-2, 310P-3 and 310P-4 of bank 306P generate respective output signals Q_PCHAN[15:0], Q_PCHAN[31:16], Q_PCHAN[47:32] and Q_PCHAN[63:48], which also may be viewed as comprising different portions of a single digital output signal.

All of the flip-flops of the register banks 306N and 306P also have reset inputs that receive the reset signal RSTN, which is an active low signal in the present embodiment. The RSTN signal ensures that the flip-flops remain cleared when a measurement is not being performed.

Although the thermometer encoded register 306 is implemented using two banks of 64 flip-flops in the present embodiment, registers having a wide variety of other sizes and configurations may be used in other embodiments.

As noted above, the digital output signals comprising data outputs of the flip-flops of the first and second banks of flip-flops 306N and 306P in the thermometer encoded register 306 are indicative of aging effects in transistors of the first and second delay lines 302 and 304. More particularly, these output signals separately and simultaneously provide measurements of the aging effects experienced by NMOS and PMOS transistors of the first and second delay lines 302 and 304.

The delay lines 302 and 304 in the present embodiment are configured so as to permit selective aging of both NMOS and PMOS transistors. More particularly, the differential inputs of each delay line are driven by respective complementary signals such that after the transistors of the delay line are subjected to aging under fixed bias input conditions, one of the complementary signals will show aging effects on only the falling edge of a pulse moving through the delay line, while the other complementary signal will show aging effects on only the rising edge of the pulse. As will be described in more detail below, this allows separate and simultaneous measurement of NMOS and PMOS aging effects.

In the particular differential delay element configuration shown in FIG. 3B, certain transistors of the four inverters I1, I2, I3 and I4 of each delay element will exhibit aging effects while others will not, depending upon the fixed bias conditions associated with the aging.

Exemplary fixed bias conditions are shown in parentheses adjacent the inputs and outputs of the differential delay element in FIG. 3B.

As indicated previously, each of the inverters of a given one of the delay elements includes an NMOS transistor N1 and a PMOS transistor P1. Thus, for example, if the multiplexing circuitry 320 is configured for an aging period such that fixed bias condition inputs of 1 and 0 are substantially continuously applied to the respective INN and INP inputs of the first delay element DE1 of delay line 304, as indicated in FIG. 3B, only the NMOS transistor N1 of the upper series inverter I1, the PMOS transistor P1 of the lower series inverter I2, the NMOS transistor N1 of the first parallel inverter I3 and the PMOS transistor P1 of the second parallel inverter I4 will exhibit aging effects, while the remaining four transistors do not exhibit aging effects. The four transistors of delay element DE1 that exhibit aging effects under these exemplary fixed bias conditions are encircled by dashed lines in FIG. 3B.

Accordingly, when the multiplexing circuitry 320 is subsequently reconfigured at the end of the aging period to replace the fixed bias condition inputs with the complementary inputs PLS_INV_N and PLS_INV_P, a rising edge of the OP output of DE1 is controlled by the PMOS transistors of the delay element that do not exhibit aging effects (i.e., P1 of I1 and P1 of I3), while a falling edge of the OP output of DE1 is controlled by the NMOS transistors of the delay element that do exhibit aging effects (i.e., N1 of I1 and N1 of I3). As a result, only the falling edge of the OP output of the first delay element DE1 will show aging effects. The transistors of the other delay elements of the delay line are impacted or not impacted by aging in a similar manner. A given OP rising edge will therefore experience the same propagation delay through the delay line both before and after aging, while the corresponding OP falling edge will experience a longer propagation delay through the delay line after the aging as compared to before the aging. Moreover, these aging effects are due exclusively to aging of NMOS transistors.

Similarly, a rising edge of the ON output of DE1 is controlled by the PMOS transistors of the delay element that do exhibit aging effects (i.e., P1 of I2 and P1 of I4), while a falling edge of the ON output of DE1 is controlled by the NMOS transistors of the delay element that do not exhibit aging effects (i.e., N1 of I2 and N1 of I4). As a result, only the rising edge of the ON output of the first delay element DE1 will show aging effects. As noted above, the transistors of the other delay elements of the delay line are impacted or not impacted by aging in a similar manner. A given ON falling edge will therefore experience the same propagation delay through the delay line both before and after aging, while the corresponding ON rising edge will experience a longer propagation delay through the delay line after the aging as compared to before the aging. Moreover, these aging effects are due exclusively to aging of PMOS transistors.

As indicated previously, this exemplary arrangement in which one complementary signal shows aging effects on only the falling edge of a pulse moving through the delay line, while the other complementary signal shows aging effects on only the rising edge of the pulse, allows separate and simultaneous measurement of NMOS and PMOS aging effects.

More particularly, in the FIG. 3 embodiment, the clock signals CP1 through CP8 applied to the rising edge clocked flip-flops of the thermometer coded register banks 306N and 306P are all controlled by a rising edge of an OP signal, namely the OP output of DE46, which as mentioned above does not exhibit aging effects. The flip-flops of the register banks 306N and 306P receive as their data inputs the respective OP[63:0] and ON[63:0] signals. Thus, the rising edge of a given clock signal not subject to aging effects is applied to a flip-flop that receives a data input that exhibits a propagation delay increase due to aging effects. This allows the thermometer register banks 306N and 306P to measure the delay time before and after aging, with the difference providing a measure of the amount of aging experienced by respective NMOS and PMOS transistors of the delay line.

These measurements can be made very quickly using the respective thermometer coded register banks 306N and 306P of the transistor aging effects sensor, in an amount of time that is orders of magnitude less than the typical recovery time of the impacted transistors, such that the measurements are highly accurate and not adversely influenced by recovery. For example, in some implementations of the FIG. 3 embodiment of the transistor aging effects sensor 110, the measurements can be made in approximately 3.5 nanoseconds. This is about three orders of magnitude less than the typical recovery time.

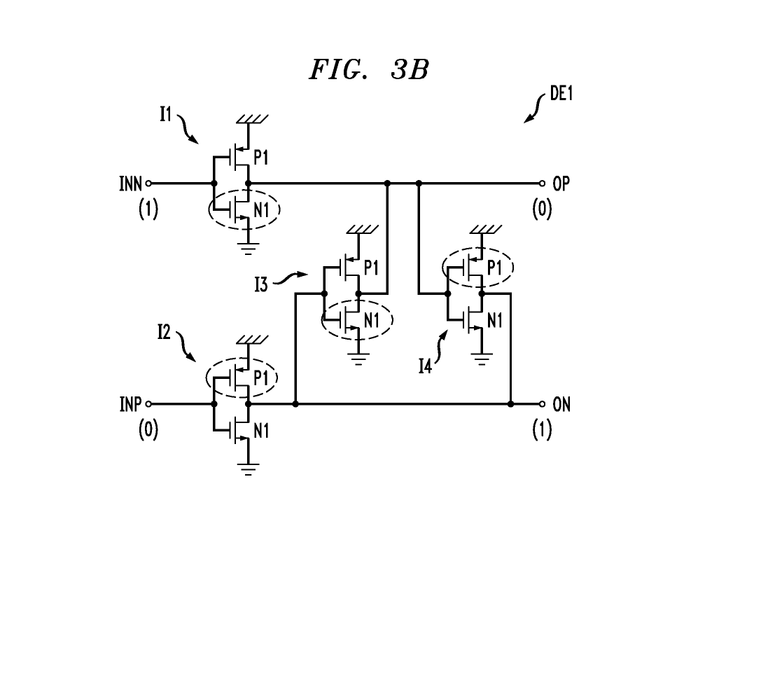

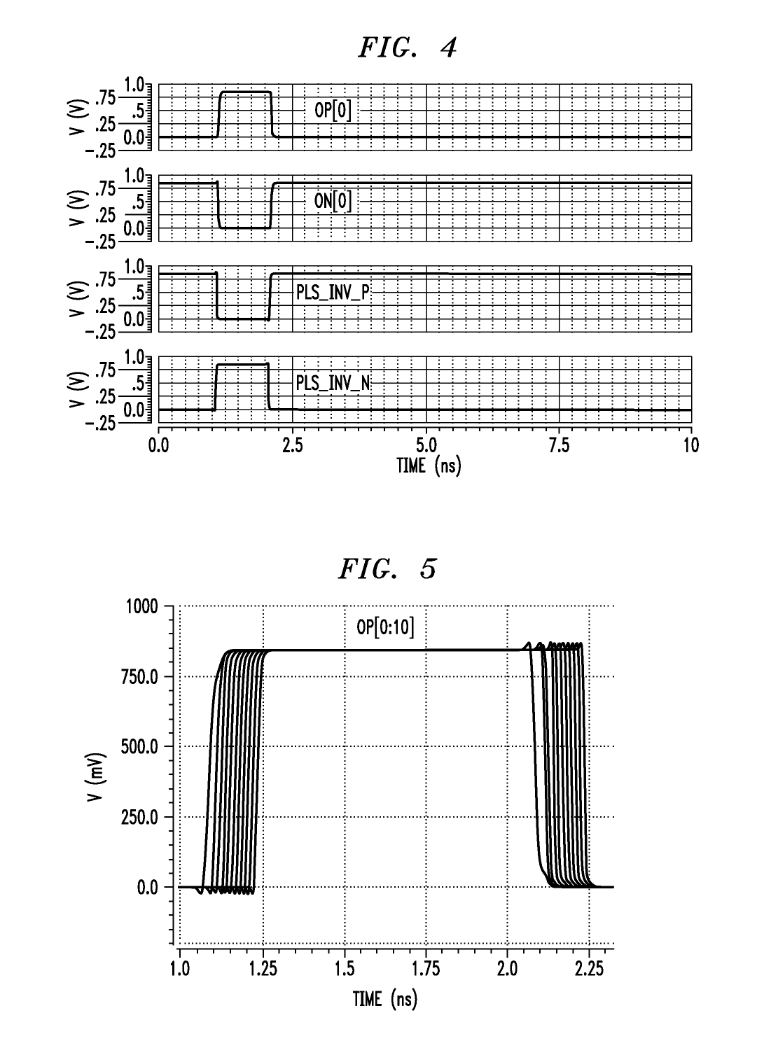

The operation of the transistor aging effects sensor 110 of FIG. 3 will now be described in greater detail with reference to the timing diagrams of FIGS. 4 through 15. In these timing diagrams, various signals of the FIG. 3 embodiment of the transistor aging effects sensor 110 are illustrated in terms of voltage in volts (V) or millivolts (mV) as a function of time in nanoseconds (ns). Simulations were run to illustrate the effects of a 10-year aging period under fixed bias conditions.

The FIG. 4 timing diagram shows the complementary signals ON0 and OP0 at the respective outputs of XOR gates 312 and 314, as well as the complementary signals PLS_INV_N and PLS_INV_P at the respective outputs of XOR gates 316 and 318. Each of these signals includes a pulse generated by assertion and subsequent deassertion of the PULSE signal. FIG. 5 shows the corresponding signals OP[0:10], where OP[1:10] denotes the OP outputs of the respective first ten delay elements DE[1:10] of the delay line 302 and OP [0] denotes the OP0 input to the delay line 302.

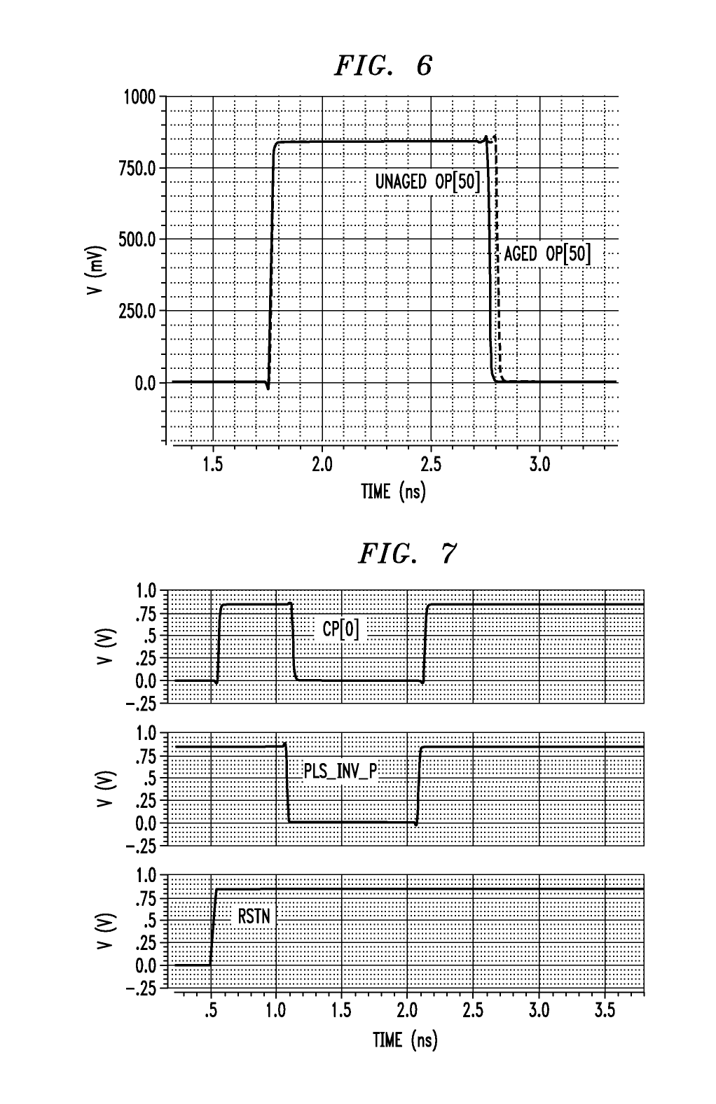

The timing diagrams of FIGS. 6 through 10 illustrate the detection of aging effects in NMOS transistors using the thermometer encoded register bank 306N.

FIG. 6 shows the signal pulse at an arbitrary output of delay line 302, namely, at output OP[50] of delay element DE50, both before and after the simulated aging. The inputs to the delay line 302 correspond to the complementary signals ON0 and OP0 illustrated in FIG. 4. It can be seen from the timing diagram that the propagation delay of the rising edge of the OP[50] pulse is unaffected by aging, while the falling edge experiences an increase in propagation delay after aging.

FIG. 7 illustrates the generation of the CP0 input to the delay line 304 by multiplexer 320P responsive to the RSTN signal. When RSTN is asserted, or at a logic low level in this example, the CP0 signal is held to the logic 0 level and the corresponding CN0 signal is held at the logic 1 level, so as to provide fixed bias conditions to the transistors of the delay line 304 for a designated aging period. When RSTN is subsequently deasserted, the pulse of the PLS_INV_P signal is propagated through multiplexer 320P to the CP0 input of the delay line 304. Although not illustrated in this diagram, the pulse of the PLS_INV_N signal is similarly propagated through multiplexer 320N to the CN0 input of the delay line 304.

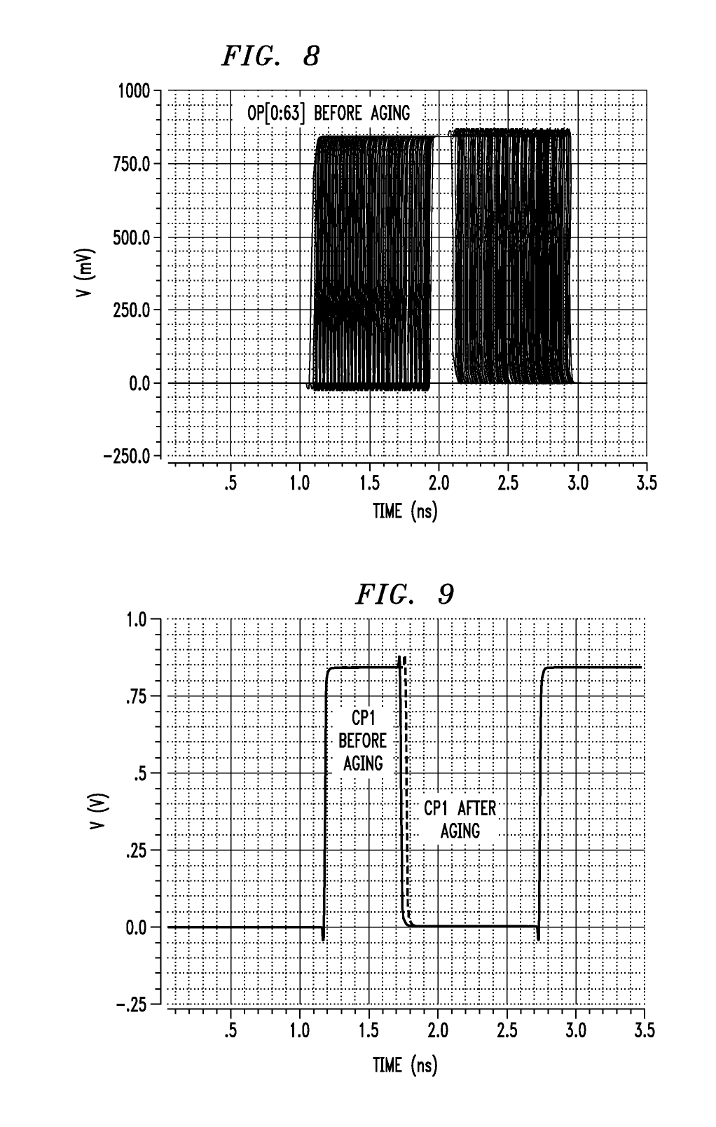

FIG. 8 shows the signal pulse at the OP0 input to the delay line 302 and the signal pulses at the 63 different OP outputs OP[1:63] of the delay line 302, before the simulated aging. Each OP output pulse shown in the diagram is delayed by an amount that is determined by the position of its corresponding delay element in the delay line 302.

FIG. 9 shows one of the clock signals, namely, clock signal CP1, both before and after aging. As described previously with reference to FIG. 3, the clock signal CP1 is derived from the OP output of DE46 of delay line 304. Due to the fixed bias conditions imposed during aging, the falling edge of CP1 exhibits an increase in propagation delay after aging, but the rising edge of CP1 does not exhibit any such aging effect. The other clock signals CP2, CP3 and CP4 similarly exhibit aging effects on their falling edges but not their rising edges.

The FIG. 3 embodiment is configured to utilize the second rising edge of clock signals CP[1:4] to latch all 64 of the OP outputs OP [0:63] of the delay line 302 at substantially the same time in the respective flip-flops of the register bank 306N, both before and after aging. Thus, the difference between the Q_NCHAN[0:63] output measurements of the register bank 306N before and after aging indicates the magnitude of the aging effects experienced by the NMOS transistors for the aging period.

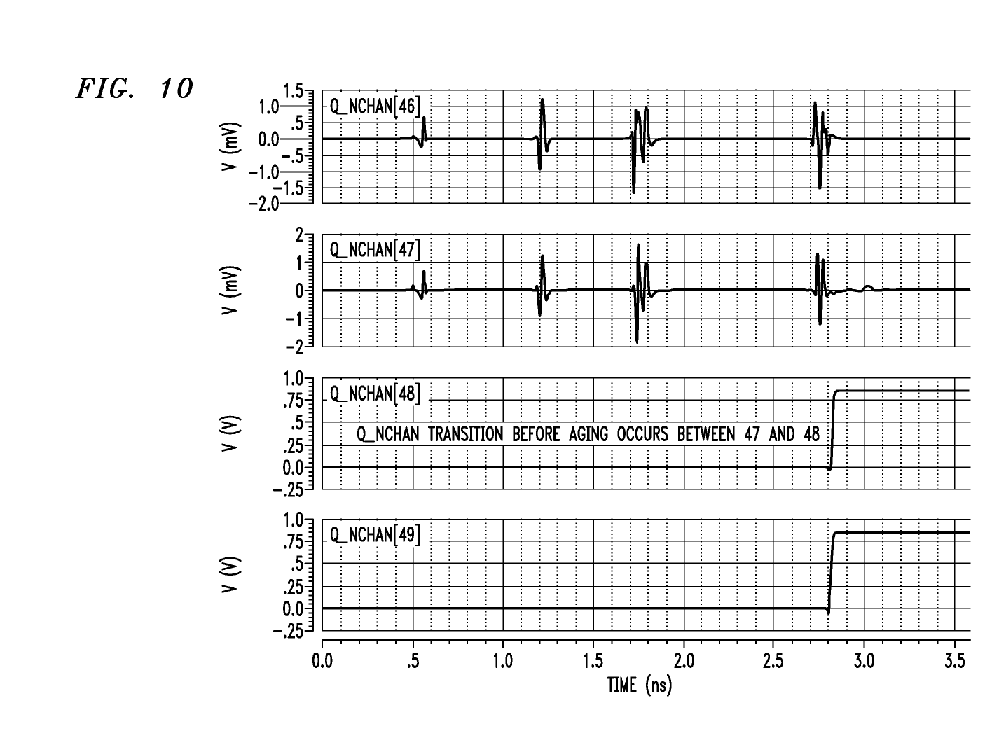

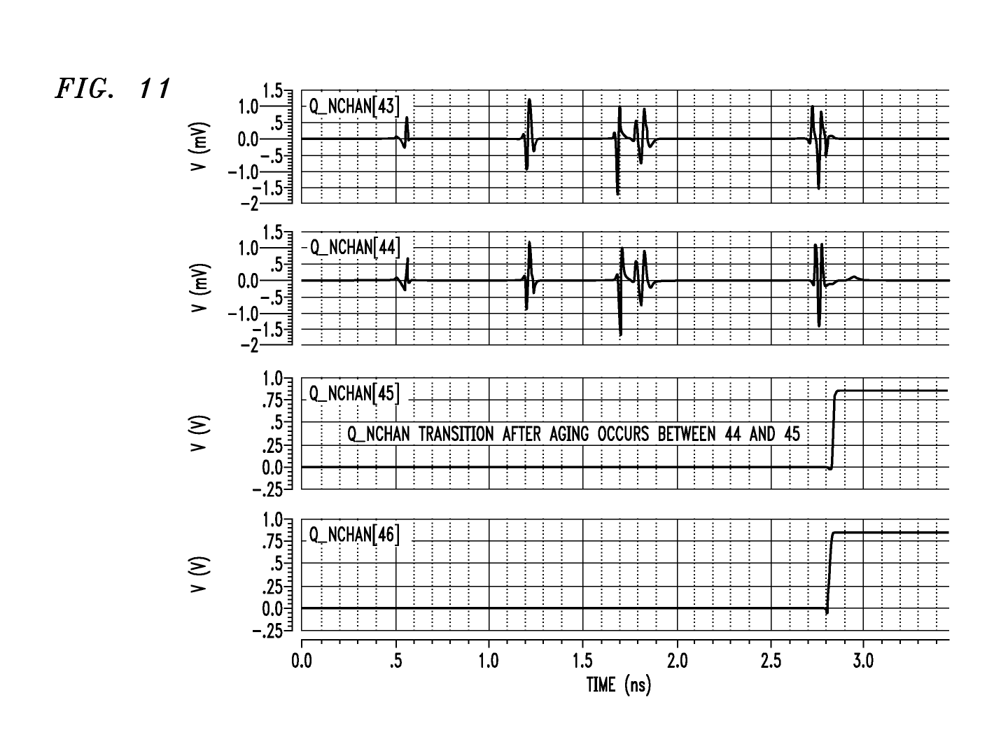

This is illustrated in FIGS. 10 and 11 for respective before aging and after aging measurements of the register bank 306N. Before aging, the Q_NCHAN[0:63] output transition occurs between Q_NCHAN[47] and Q_NCHAN[48], as shown in FIG. 10. This is because the earlier delay elements in delay line 302 provide a sufficiently small propagation delay that the 0→1→0 pulse completely passes before the CP[1:4] clocks can latch its logic high level into the flip-flops, resulting in logic low outputs for Q_NCHAN[47] and below. Eventually, as the pulse travels down the delay line 302, enough propagation delay accumulates that the CP[1:4] clocks latch the logic high level of the pulse, resulting in logic high outputs for Q_NCHAN[48] and above. After aging, the Q_NCHAN[0:63] output transition occurs between Q_NCHAN[44] and Q_NCHAN[45], as shown in FIG. 11, resulting in logic low outputs for Q_NCHAN[44] and below, and logic high outputs for Q_NCHAN[45] and above.

The timing diagrams of FIGS. 12 through 15 illustrate the detection of aging effects in PMOS transistors using the thermometer encoded register bank 306P.

FIG. 12 shows the signal pulse at the ON0 input to the delay line 302 and the signal pulses at the 63 different ON outputs ON[1:63] of the delay line 302, before the simulated aging. Each ON output pulse shown in the diagram is delayed by an amount that is determined by the position of its corresponding delay element in the delay line 302.

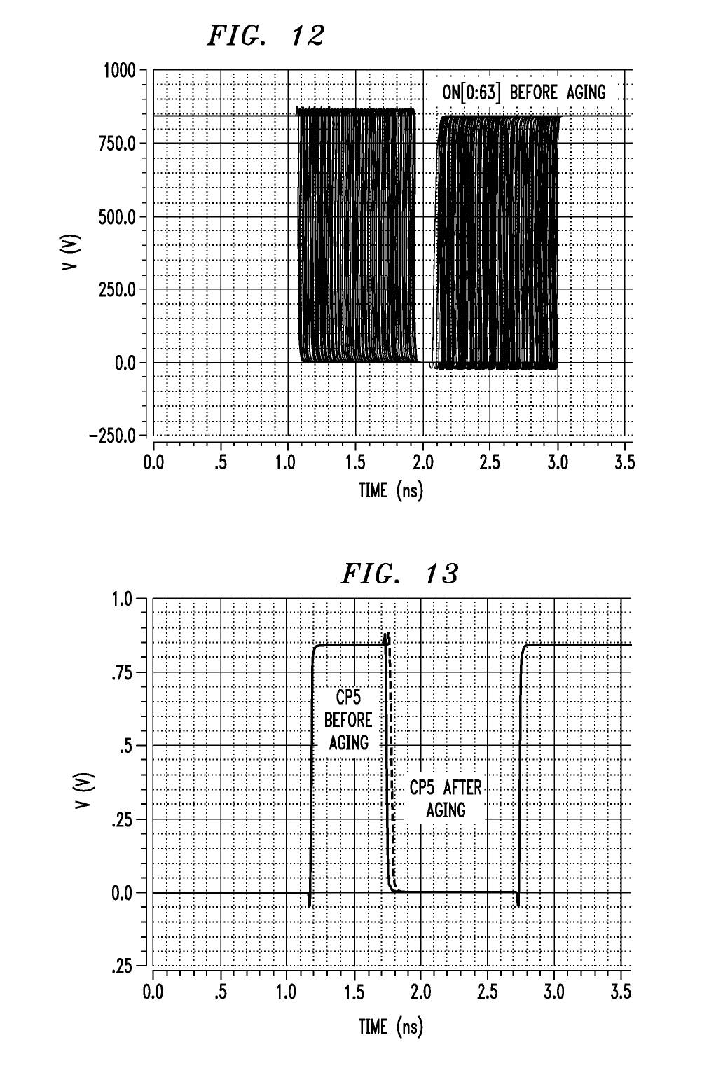

FIG. 13 shows one of the clock signals, namely, clock signal CP5, both before and after aging. As described previously with reference to FIG. 3, the clock signal CP5 is derived from the OP output of DE46 of delay line 304. Due to the fixed bias conditions imposed during aging, the falling edge of CP5 exhibits an increase in propagation delay after aging, but the rising edge of CP5 does not exhibit any such aging effect. The other clock signals CP6, CP7 and CP8 similarly exhibit aging effects on their falling edges but not their rising edges.

The FIG. 3 embodiment is configured to utilize the second rising edge of clock signals CP[5:8] to latch all 64 of the ON outputs ON[0:63] of the delay line 302 at substantially the same time in the respective flip-flops of the register bank 306P, both before and after aging. Thus, the difference between the Q_PCHAN[0:63] output measurements of the register bank 306P before and after aging indicates the magnitude of the aging effects experienced by the PMOS transistors for the aging period.

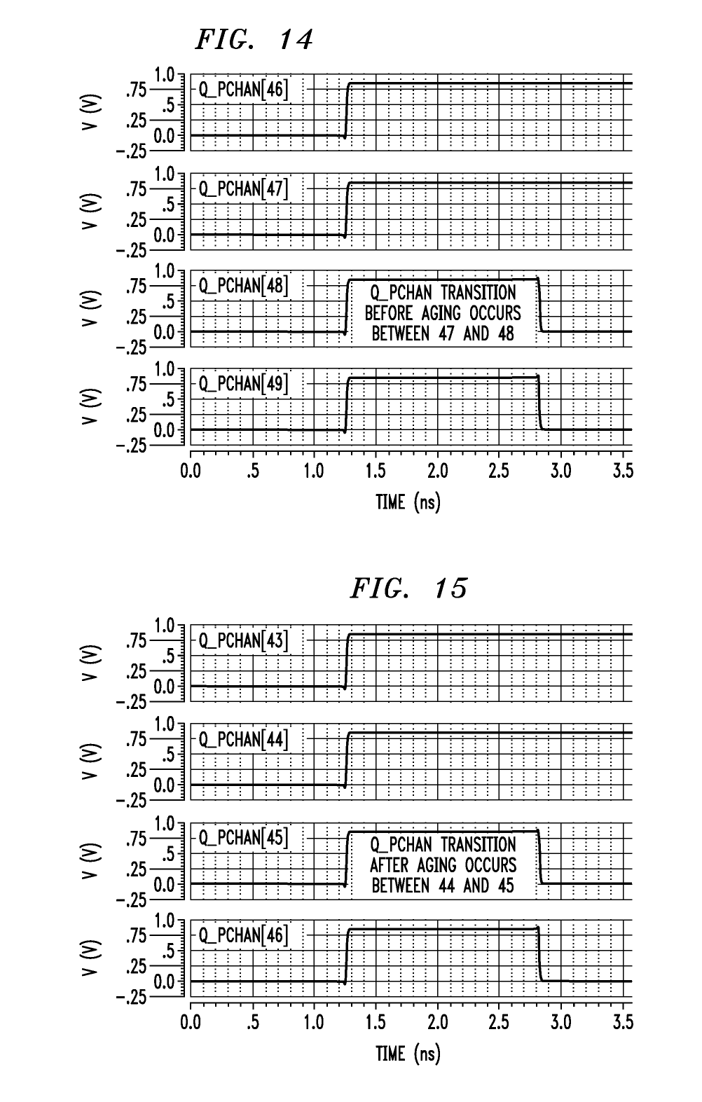

This is illustrated in FIGS. 14 and 15 for respective before aging and after aging measurements of the register bank 306P. Before aging, the Q_PCHAN[0:63] output transition occurs between Q_PCHAN[47] and Q_PCHAN[48], as shown in FIG. 14. This is because the earlier delay elements in delay line 302 provide a sufficiently small propagation delay that the 1→0→1 pulse completely passes before the CP[5:8] clocks can latch its logic low level into the flip-flops, resulting in logic high outputs for Q_PCHAN[47] and below. Eventually, as the pulse travels down the delay line 302, enough propagation delay accumulates that the CP[5:8] clocks latch the logic low level of the pulse, resulting in logic low outputs for Q_PCHAN[48] and above. After aging, the Q_PCHAN[0:63] output transition occurs between Q_PCHAN[44] and Q_PCHAN[45], as shown in FIG. 15, resulting in logic high outputs for Q_PCHAN[44] and below, and logic low outputs for Q_PCHAN[45] and above.

The above-described before and after aging measurements from the register banks 306N and 306P in hexadecimal format are as follows:

BEFORE: Q_NCHAN <63:0>=FFFF_{—}0000_{—}0000_{—}0000

AFTER: Q_NCHAN <63:0>=FFFF_E000_{—}0000_{—}0000

BEFORE: Q_PCHAN <63:0>=0000_FFFF_FFFF_FFFF

### AFTER: Q_PCHAN <63:0>=0000_{—}1FFF_FFFF_FFFF

Again, in this example, the difference between the before and after aging effects measurements for both NMOS and PMOS transistors corresponds to three delay elements of the delay line 302.

In a given implementation, the PULSE and RSTN signals are maintained at logic low levels during aging. The before aging measurement may be made early in the lifetime of the integrated circuit, by appropriate control of the PULSE and RSTN signals, and the results stored in a memory. After aging, another measurement is taken and compared to the previously-stored before aging measurement in order to determine the extent of the aging effects as reflected in the difference between the two measurements.

The transistor aging effects sensor 110 of FIG. 3 provides significant improvements relative to conventional arrangements. For example, it is an all-digital transistor aging effects sensor in which measurements are substantially independent of voltage and temperature. Also, due to the self-timed configuration of the sensor, the measurements are substantially independent of clock frequency. Moreover, the transistor aging effects sensor can be implemented so as to consume dynamic power only when making a measurement, and therefore without unduly increasing the power consumption of the corresponding integrated circuit. It should be noted, however, that the sensor consumes leakage power regardless of whether or not measurements are being made, and this leakage power will generally be dependent upon factors such as temperature and process variations.

The transistor aging effects sensor 110 in the illustrative embodiments can be used to track aging-related performance issues in the integrated circuit, so that appropriate remedial actions can be taken. This type of accurate tracking of aging effects could lead to a reduction in the design margin required to protect against aging effects, the magnitude of which is generally unknown at design time. As transistor aging in one or more embodiments is implemented using fixed bias conditions, the aging effects determination can provide a worst case assessment of the aging effects.

The transistor aging effects sensor 110 also provides a readily scalable measurement resolution, in that resolution can be increased by simply increasing the length of the delay lines 302 and 304.

It is to be appreciated that the particular testing system, tester and transistor aging effects sensor arrangements shown in FIGS. 1-3 are presented by way of illustrative example only, and numerous alternative arrangements of circuitry and other system elements may be used to implement transistor aging effects sensing functionality in the manner disclosed herein.

For example, as indicated previously, the delay lines in other embodiments may be implemented using respective inverter chains in which the delay elements comprise respective inverters. These and other arrangements may be configured to permit measurement of aging effects by isolating these aging effects to only a subset of the transistors of the inverter chains. In a given such inverter chain comprising a series arrangement of inverters each having an NMOS transistor and a PMOS transistor, under a fixed bias condition of an input 0 value, the PMOS transistor of the first inverter, the NMOS transistor of the second inverter, the PMOS transistor of the third inverter, and so on, exhibit aging effects, while the remaining transistors do not exhibit aging effects.

One can therefore latch in a thermometer encoded register alternating rising and falling edges of delay line signals that exhibit aging effects. The latching clock would be selected such that it did not exhibit aging effects. Since the thermometer encoded register in this example would be latching alternating 1 and 0 levels, the output of every second flip-flop of the register should be inverted. Differences in the timing of the before aging and after aging transitions would again indicate the extent of the aging effects.

It should be noted, however, that in such an arrangement the aging effects for the NMOS transistors are not separated from the aging effects for the PMOS transistors, and accordingly the sensor output will indicate an average of NMOS and PMOS transistor aging effects.

In another possible variant of the FIG. 3 embodiment, the second delay line 304 could be configured so as to exhibit no aging effects at all. Instead, the second delay line could be disconnected from its Vdd voltage supply during normal operation of the integrated circuit, and reconnected to Vdd only when an aging effects measurement is to be made. In one embodiment of such an arrangement, the D0 inputs to multiplexers 320N and 320P could both be connected to a logic low level, such that logic low levels are applied to both the INN and INP inputs of the delay line 304. It should be noted that the RSTN signal should be set to a logic high level well before the Vdd supply is reconnected, in order to prevent excessive current flow in the delay line 304. The delay elements of the delay line when powered up will temporarily experience the input condition INN=INP=0. However, setting RSTN to the logic high level will ensure that the multiplexers 320N and 320P provide a valid complementary signal pair to the INN and INP inputs of the delay line 304. In this arrangement, as indicated previously, there are no aging effects exhibited by either the rising or falling edges of the signals propagating through the delay line, and so either a rising edge or a falling edge of such a signal may be used to clock the flip-flops of the register at the appropriate time.

In yet another variant of the FIG. 3 embodiment, an additional delay line similar to delay line 302 may be incorporated into the transistor aging effects sensor 110, but configured to have its Vdd supply disconnected during aging, such that its transistors will not exhibit any aging effects. After aging, its Vdd supply is reconnected, and complementary signals through this delay line are latched in a register bank to provide what is effectively a before aging measurement. This type of arrangement avoids the need to take a before aging measurement early in the lifetime of the integrated circuit, as well as the need to store the measurement results for potentially long periods of time. Instead, both the before aging measurement and the after aging measurement can be taken at substantially the same time using different instances of the delay line 302.

The above variants involving disconnection of supply voltage to at least one delay line can also be implemented using delay lines comprising inverter chains, but again, this would result in an arrangement that provides a measurement of average aging effects of both NMOS and PMOS transistors.

As indicated previously, embodiments of the invention may be implemented in the form of integrated circuits. In a given such integrated circuit implementation, identical die are typically formed in a repeated pattern on a surface of a semiconductor wafer. Each die includes at least one transistor aging effects sensor as described herein, and may include other structures or circuits. The individual die are cut or diced from the wafer, then packaged as an integrated circuit. One skilled in the art would know how to dice wafers and package die to produce integrated circuits. Integrated circuits so manufactured are considered embodiments of this invention.

It should once again be emphasized that the embodiments of the invention as described herein are intended to be illustrative only. For example, other embodiments of the invention can be implemented using a wide variety of different types of logic gates and other circuitry, providing different configurations of aging effects sensors and associated registers. Also, different input and output signaling arrangements may be utilized. These and numerous other alternative embodiments within the scope of the following claims will be readily apparent to those skilled in the art.

What is claimed is:

1. An apparatus comprising:
first and second delay lines each comprising a plurality of delay elements; and
a register comprising a plurality of flip-flops having data inputs driven by respective outputs of respective ones of the delay elements of the first delay line and clock inputs driven by one or more clock signals provided by at least one of the delay elements of the second delay line;
wherein data outputs of the flip-flops of the register are indicative of one or more aging effects in transistors of the first and second delay lines.

2. The apparatus of claim 1 wherein the first and second delay lines comprise respective differential delay lines in which the delay elements comprise respective differential delay elements.

3. The apparatus of claim 2 wherein a given one of the differential delay elements comprises four inverters, including two series inverters that pass respective ones of two delay element inputs to two corresponding outputs, and a pair of cross-coupled inverters connected between the two outputs.

4. The apparatus of claim 1 wherein the first and second delay lines comprise respective inverter chains in which the delay elements comprise respective inverters.

5. The apparatus of claim 2 further comprising an input circuit configured to generate a first set of complementary input signals for application to differential inputs of the first differential delay line and a second set of complementary input signals for application to differential inputs of the second differential delay line.

6. The apparatus of claim 5 wherein the first and second sets of complementary input signals are generated from a common pulse input signal.

7. The apparatus of claim 5 wherein the complementary input signals within a given one of the first and second sets of complementary input signals have substantially aligned transition times.

8. The apparatus of claim 5 wherein the input circuit comprises:
a first set of logic gates configured to generate the first set of complementary input signals for application to the first differential delay line; and
a second set of logic gates configured to generate the second set of complementary input signals for application to the second differential delay line.

9. The apparatus of claim 8 wherein a given one of the sets of logic gates comprises first and second exclusive-or gates, with the first exclusive-or gate having a first input coupled to an upper supply voltage and a second input coupled to a pulse input signal line, and the second exclusive-or gate having a first input coupled to the pulse input signal line and a second input coupled to a lower supply voltage.

10. The apparatus of claim 5 wherein the input circuit further comprises multiplexing circuitry configured to selectively adapt the second set of complementary input signals so as to comprise a set of fixed bias condition input signals for application to the differential inputs of the second differential delay line.

11. The apparatus of claim 1 wherein the register comprises a thermometer encoded register providing at least one digital output signal that is utilized to determine one or more aging effects in transistors of the first and second delay lines.

12. The apparatus of claim 1 wherein the register comprises:
a first bank of flip-flops providing at least one digital output signal that is utilized to determine one or more aging effects in NMOS transistors of the first and second delay lines; and
a second bank of flip-flops providing at least one digital output signal that is utilized to determine one or more aging effects in PMOS transistors of the first and second delay lines.

13. The apparatus of claim 12 wherein the flip-flops of the first bank of flip-flops have data inputs driven by respective first outputs of respective differential delay elements of the first delay line and clock inputs driven by a first set of clock signals provided by at least one of the delay elements of the second delay line, and wherein the flip-flops of the second bank of flip-flops have data inputs driven by respective second outputs of respective differential delay elements of the first delay line and clock inputs driven by a second set of clock signals provided by at least one of the delay elements of the second delay line.

14. The apparatus of claim 1 wherein the apparatus is implemented in the form of an integrated circuit.

15. A method comprising:
driving data inputs of flip-flops of a register with respective outputs of respective ones of a plurality of delay elements of a first delay line; and
driving clock inputs of the flip-flops of the register with one or more clock signals provided by at least one of the delay elements of a second delay line;
wherein data outputs of the flip-flops of the register are utilized to determine one or more aging effects in transistors of the first and second delay lines.

16. The method of claim 15 further comprising:
utilizing a first set of data outputs of a first bank of flip-flops of the register to determine one or more aging effects in NMOS transistors of the first and second delay lines; and
utilizing a second set of data outputs of a second bank of flip-flops of the register to determine one or more aging effects in PMOS transistors of the first and second delay lines.

17. The method of claim 15 further comprising determining one or more aging effects in transistors of the first and second delay lines by comparing a current digital value of the data outputs measured after completion of an aging period to a baseline digital value of the data outputs measured before start of the aging period.

18. A computer program product comprising a computer-readable storage medium having computer program code embodied therein, wherein the computer program code when executed causes the method of claim 15 to be performed.

19. An apparatus comprising:
a tester comprising a processor coupled to a memory;
wherein the tester is configured to generate one or more control signals for controlling a transistor aging effects sensor of an integrated circuit, the transistor aging effects sensor comprising:
first and second delay lines each comprising a plurality of delay elements; and
an register comprising a plurality of flip-flops having data inputs driven by respective outputs of respective ones of the delay elements of the first delay line and clock inputs driven by one or more clock signals provided by at least one of the delay elements of the second delay line;
wherein the tester is further configured to utilize data outputs of the flip-flops of the register to determine one or more aging effects in transistors of the first and second delay lines.

20. The apparatus of claim 19 where the tester is at least partially implemented within the integrated circuit.
